(19) United States
(12) Patent Application Publication
(10) Pub. No.: US 2006/0272850 A1
(43) Pub. Date: Dec. 7, 2006

(54) INTERLAYER CONNECTION CONDUCTOR AND MANUFACTURING METHOD THEREOF

(75) Inventors: Shinji MORIMOTO, Fukuoka (JP); Toyokazu YOSHINO, Fukuoka (JP); Shigeki OGATA, Fukuoka (JP); Kouji NAKASHIMA, Fukuoka (JP); Katsuya OKAMOTO, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/422,164

(22) Filed: Jun. 5, 2006

(30) Foreign Application Priority Data
Sep. 26, 2005 (JP) 2005/277758
Jun. 6, 2005 (JP) 2005/165125

(51) Int. Cl. H05K 1/00

(52) U.S. Cl. 174/254; 29/852; 29/255; 174/264; 29/829; 427/309

(57) ABSTRACT

An interlayer connection conductor 1 is formed of a substantially spherical interlayer connector that is formed by forced in through holes 108, in a thickness direction, on a flexible printed circuit board having wiring layers 106, 107 on at leas one surface of an insulating layer The interlayer connection conductor includes a small cylindrical piece of metal core 102 formed by cutting a metal fine wire and a solder metal 103 coated around the surface of the metal core.

### BACKGROUND OF THE INVENTION

The present invention relates to an interlayer connector of a multilayer flexible printed circuit board (hereafter, referred to as FPC) on which a variety of surface-mounting type electric components are mounted, particularly an interlayer connection conductor and manufacturing method of the same, which is used to connect wiring layers of a multilayer FPC requiring high connection reliability.

Recently, as electronic devices have decreased in size and weight and become sophisticated, the wiring concentration of the FPC involved is likely to increase. Miniaturization of a wiring layer is not enough to increase the wiring concentration of an FPC. Attention is given to a multilayer FPC having increased wiring concentration that is formed by a process of layering wiring layers, disposing interlayer connectors on an insulating layer between the wiring layers, and connecting the wiring layers in three dimensions.

In the related art, a multilayer FPC is formed by a process of forming through holes on adhesive layers formed of a polyimide film, applying copper plate on the through hole walls, and connecting the wiring layers on both side of the adhesive layers in three dimensions (Patent Document 1). Plating-through hole method is the most common method of interlayer connection.

Manufacturing method of the plating-through hole includes two main processes of applying conductivity to an insulating through hole by nonelectrolytic plating and copper thickening plating by electrolytic plating. The above-mentioned method has a feature that it has improved connection reliability against heat because of the same thermal expansive rate of the copper plating film on the inside of the through hole and the insulating layer having the through hole.

However, during the copper thickening plating, the copper plating film on the inside of the through hole increases in thickness and the thickness of a copper film that is a raw material of the wiring layer also increases. Therefore, it is difficult to miniaturize the wiring with a subsequent etching. Further, the process involved is complicated, and thus problems still remain in terms of productivity.

Method of applying melt-solidification by printing solder paste inside a through hole to overcome the above problems has been proposed (for example, Patent Document 2). The method has a feature that the productivity is improved because it requires a simple process compared with the above plating-through hole method, and the thickness of a copper in is not affected by anything in during process and miniaturization of the wiring layer is not prevented due to interlayer connection after forming the wiring layer.

However, since the thermal expansive rate of a solder is larger than that of an insulating layer, the solder inside a through hole expands more than the wiring layer. Accordingly, the joining interface between the wiring layer on the insulating layer and the solder may be separated. Therefore, as for the method using a solder, reliability in not satisfied due to heat.

JP-A-5-175636

JP-A-7-176847

Method of connecting layers by forcing substantially spherical conductor into through holes to overcome the problem that the connection reliability is not secured due to heat has been proposed. The substantially spherical conductor is formed of a core of metal member covered with a solder metal with uniform volume.

Thickening solder plating by barrel solder plating is generally known method to apply a solder metal to the surface of a metal member but it requires long time to plate to form a solder plating film with uniform thickness on the surface of the metal member. Plating solution needs to be controlled for plating film thickness control and quality control. However it is complicated and causes problems in terms of productivity.

In order to achieve a spherical shape after solder plating, the shape of a metal member of core portion needs to be spherical. However, in general method of manufacturing a metal spherical body with uniform volume to prevent non-uniform particle diameter is not suitable to mass production.

### SUMMARY OF THE INVENTION

In order to achieve a spherical shape after solder plating, the shape of a metal member of core portion needs to be spherical. However, in general, method of manufacturing a metal spherical body with uniform volume to prevent non-uniform particle diameter is not suitable to mass production.

An object of the present invention is to provide an interlayer connection conductor having high connection reliability, optimal miniaturization of a wiring layer, and improved productivity, and manufacturing the interlayer connection conductor.

According to an aspect of the invention, there is provided an interlayer connection conductor, which is formed in a substantially spherical shape and is press-fitted into a through hole formed in a flexible printed circuit board in a thickness direction so as to serve an interlayer connector, the flexible printed circuit board having a wiring layer that is formed on at least one surface of an insulating layer. The interlayer connection conductor includes a metal core that has a cylindrical small piece formed by cutting a metal fine wire, and a solder metal that covers the surface of the metal core.

According to another aspect of the invention, a method of manufacturing an interlayer connection conductor includes forming a metal core by cutting a metal fine wire in a predetermined length, disposing the cut metal core on a thermal resistant substrate having a recess, coating a solder metal to cover the metal core disposed in the recess, and covering the metal core with the solder metal in a substantially spherical shape by heating and melting the solder metal.

According to the aspects of the invention, the interlayer connection conductor for electric connection between wiring layers of a multilayer FPC includes the metal core that has a cylindrical small piece formed by cutting the metal fine wire, and the solder metal that covers the surface of the metal core. Accordingly, the interlayer connection conductor having a substantially spherical conductor with uniform volume can be obtained. Therefore, with deformation by pressure, the spherical conductor can be filled into the hole with no gap. As a result, the solder metal can be securely adhered to the wiring layer. Further, high connection reliability can be obtained because the metal core is formed of a cylindrical small piece with uniform volume.

Since the metal core has a cylindrical small piece formed by cutting the metal fine wire, the conductor can have the optimum size to the volume of the through hole. Further, since the cut metal fine wire can also be used, the productivity can be improved compared with a case where a metal ball is used as the metal core.

### BRIEF DESCRIPTION OF THE DRAWNGS

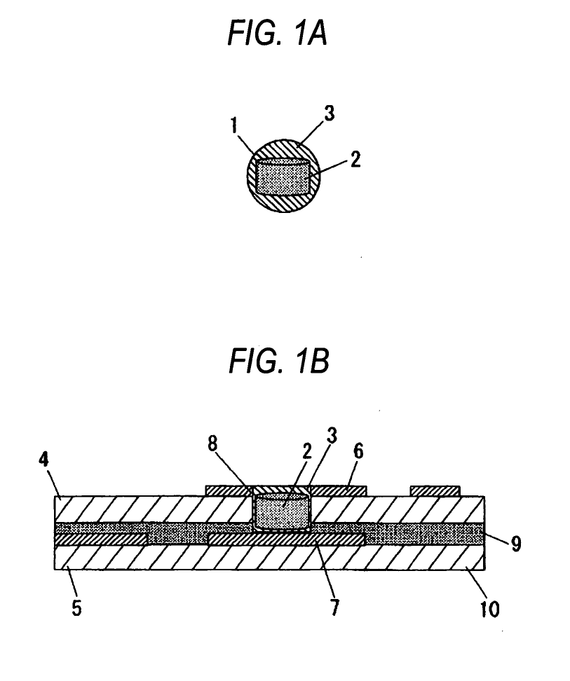

FIG. 1A is a schematic view of an interlayer connection conductor and FIG. 1B is a view of main parts of a multilayer FPC in which layers are connected through interlayer connection conductors according to an embodiment of the invention.

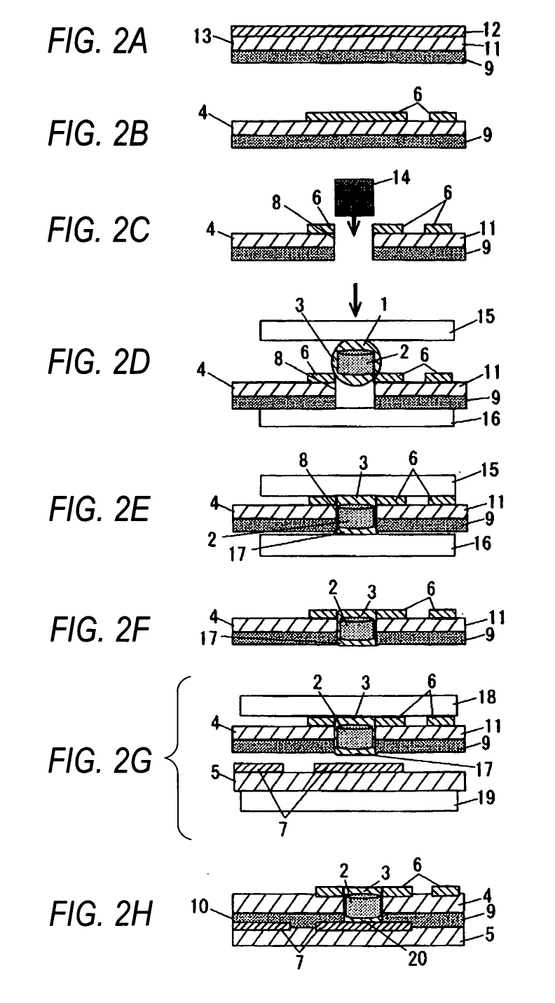

FIG. 2A is a view illustrating manufacturing method of multilayer FPC using an interlayer connection conductor according to an embodiment of the invention, FIG. 2B is a view illustrating manufacturing method of multilayer FPC using an interlayer connection conductor according to an embodiment of the invention, FIG. 2C is a view illustrating manufacturing method of multilayer FPC using an interlayer connection conductor according to an embodiment of the invention, FIG. 2D is a view illustrating manufacturing method of multilayer FPC using an interlayer connection conductor according to an embodiment of the invention, FIG. 2E is a view illustrating manufacturing method of multilayer FPC using an interlayer connection conductor according to an embodiment of the invention, FIG. 2F is a view illustrating manufacturing method of multilayer FPC using an interlayer connection conductor according to an embodiment of the invention, FIG. 2G is a view illustrating manufacturing method of multilayer FPC using an interlayer connection conductor according to an embodiment of the invention, and FIG. 2H is a view illustrating manufacturing method of multilayer FPC using an interlayer connection conductor according to an embodiment of the invention.

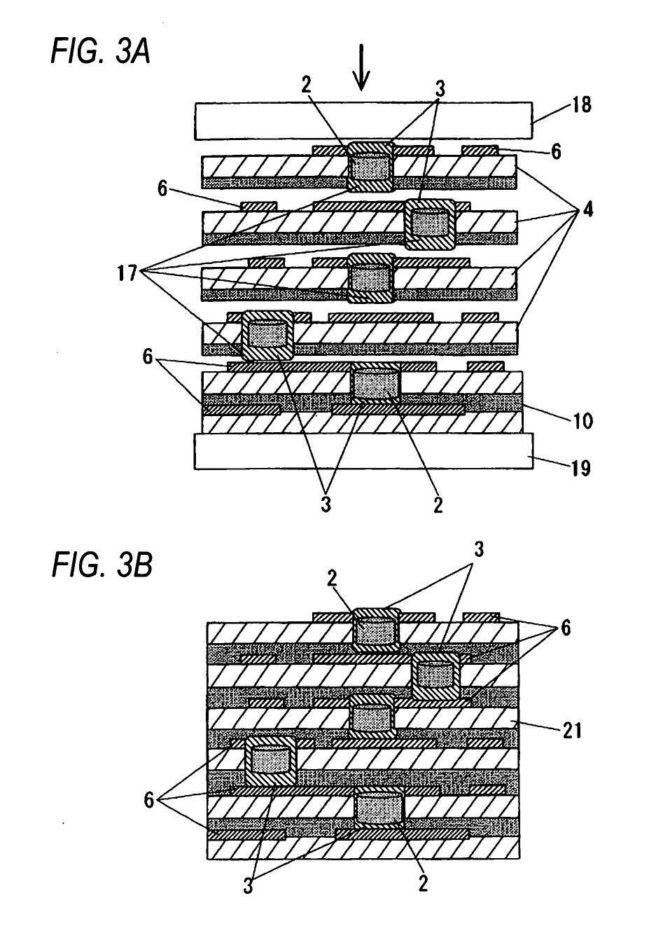

FIG. 3 is a view illustrating manufacturing method of a multilayer FPC of a further layered multilayer FPC of FIG. 2.

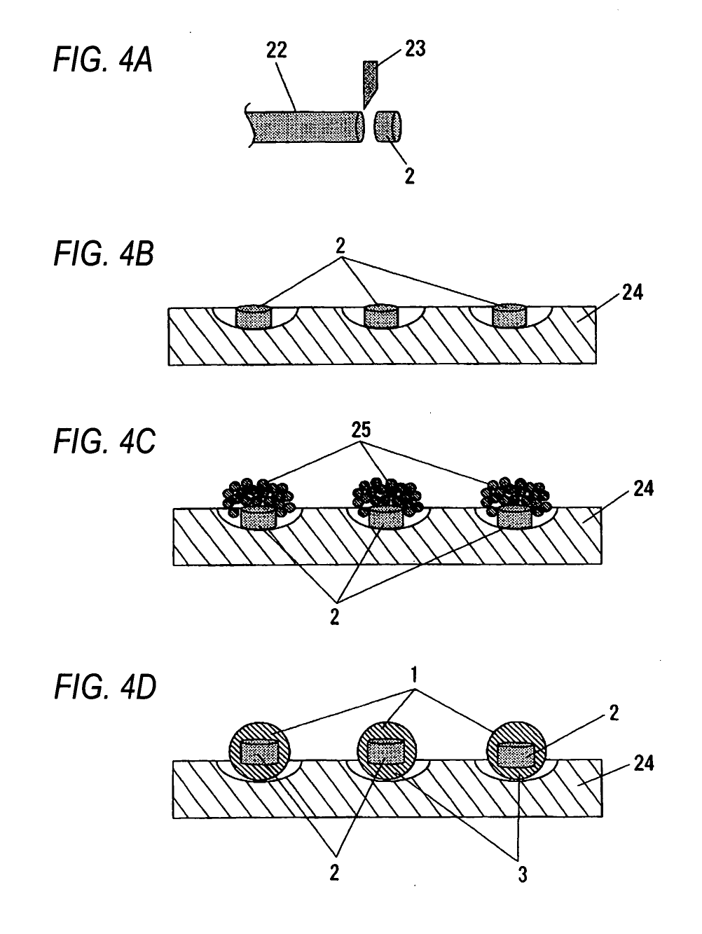

FIG. 4 is a view illustrating manufacturing method of an interlayer connection conductor according to an embodiment of the invention using solder paste.

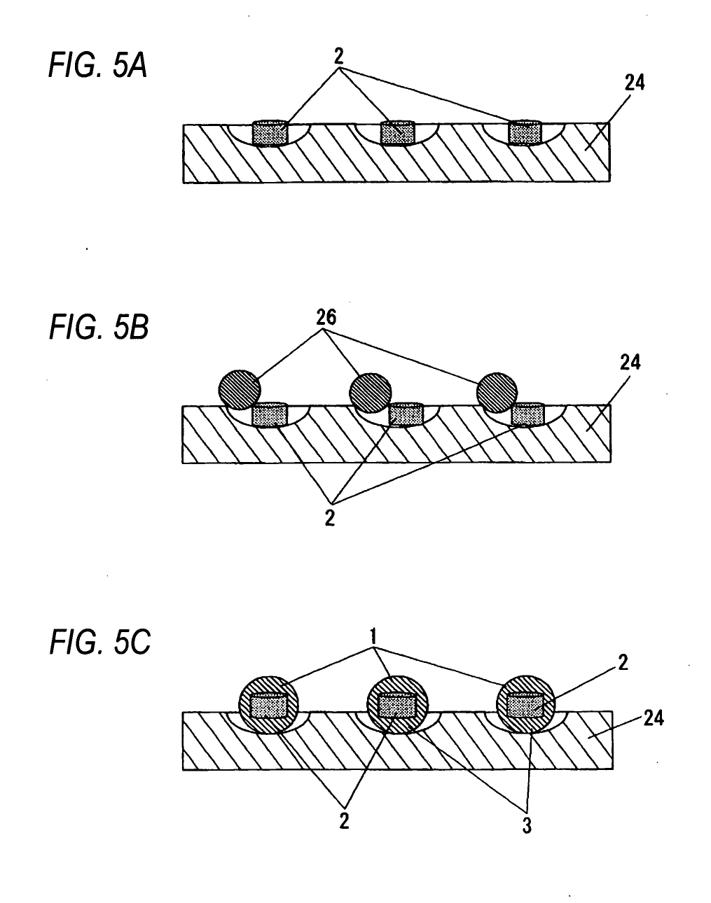

FIG. 5 is a view illustrating manufacturing method of an interlayer connection conductor according to an embodiment of the invention using a solder ball.

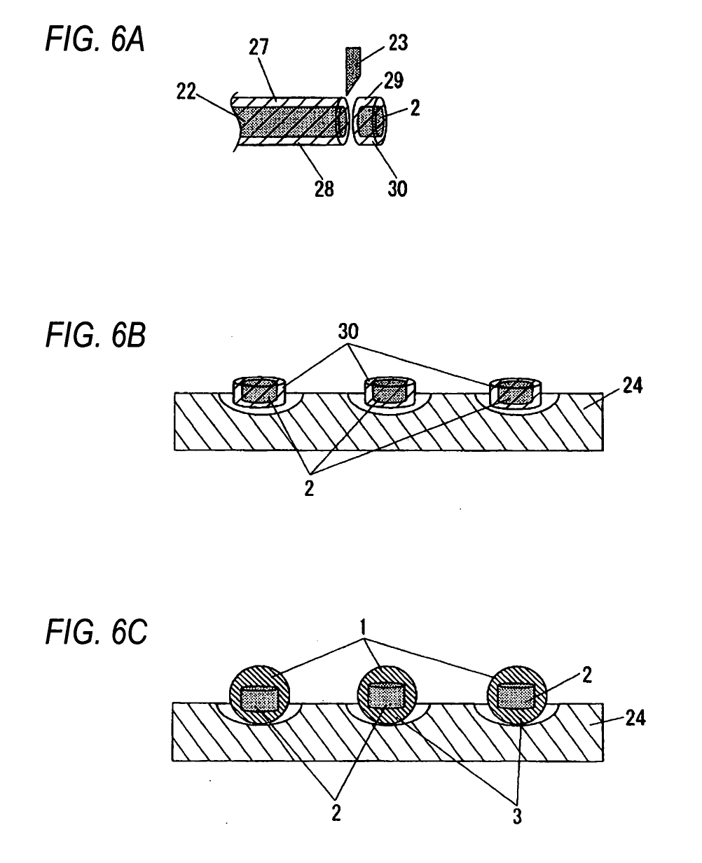

FIG. 6 is a view illustrating manufacturing method of an interlayer connection conductor according to an embodiment of the invention using a metal fine wire coated with a solder metal.

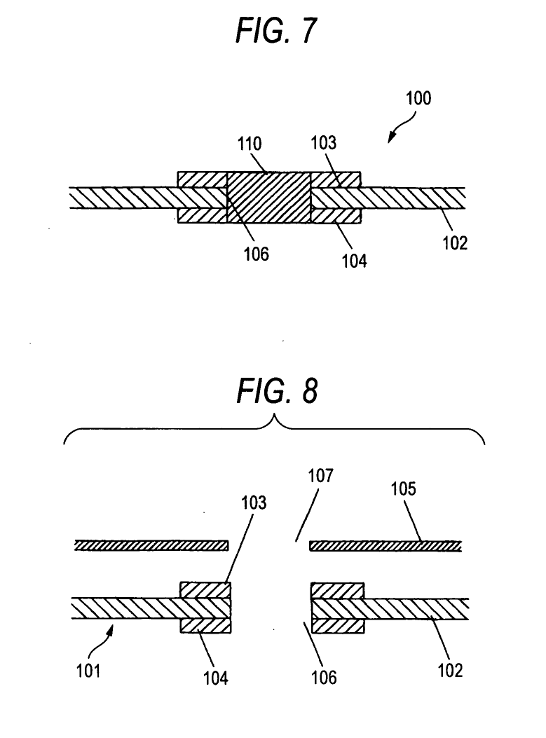

FIG. 7 is a cross-sectional view of essential parts of a multilayer flexible printed circuit board that is formed by the application of the present invention.

FIG. 8 is a cross-sectional view of the essential parts illustrating a state in which a classification mask is laid over the top surface of a double-sided flexible printed circuit board in which a through hole is formed.

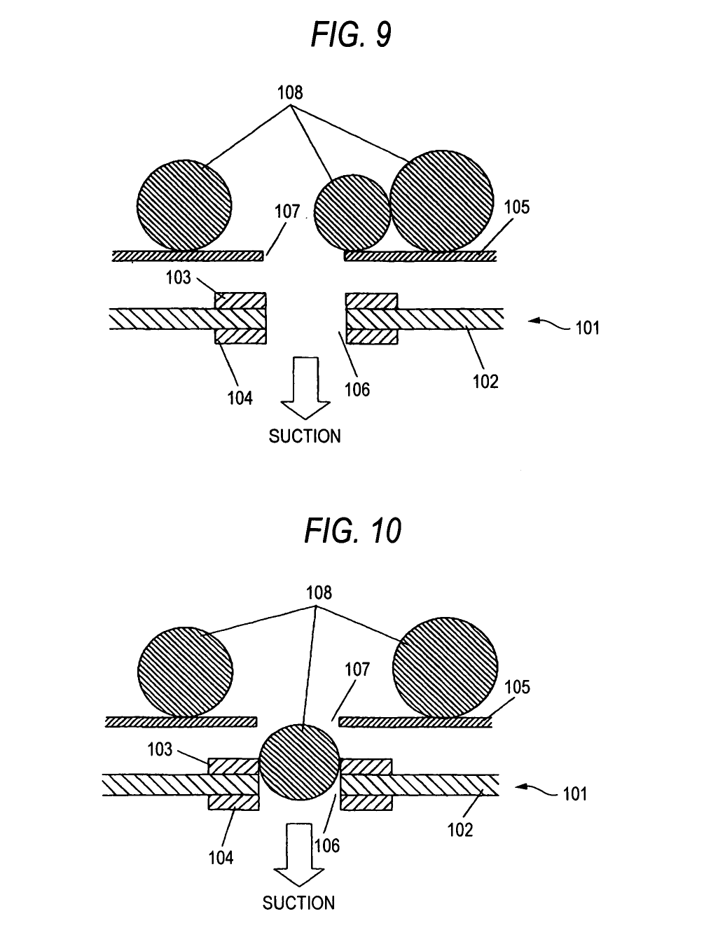

FIG. 9 is a cross-sectional view of the essential parts illustrating a state in which a substantially spherical conductor is introduced into the through hole of the double-sided flexible printed circuit board by the classification mask.

FIG. 10 is a cross-sectional view of the essential parts illustrating a state in which the substantially spherical conductor that is classified by the classification mask is suctioned into the through hole of the double-sided flexible printed circuit board.

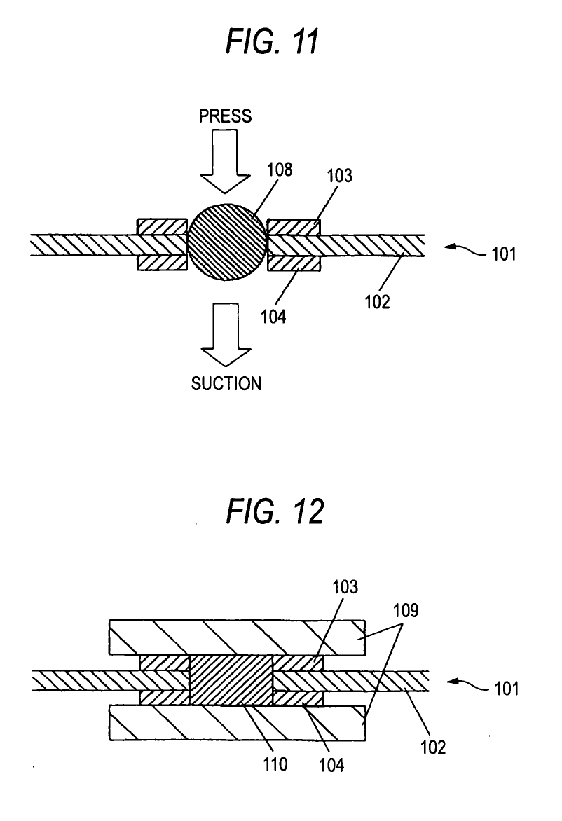

FIG. 11 is a cross-sectional view of the essential parts illustrating a state in which the substantially spherical conductor is suctioned and press-fitted into the through hole of the double-sided flexible printed circuit board.

FIG. 12 is a cross-sectional view of the essential parts illustrating a state in which the substantially spherical conductor that is press-fitted in the through hole of the double-sided flexible printed circuit board is melted to electrically connect each layer.

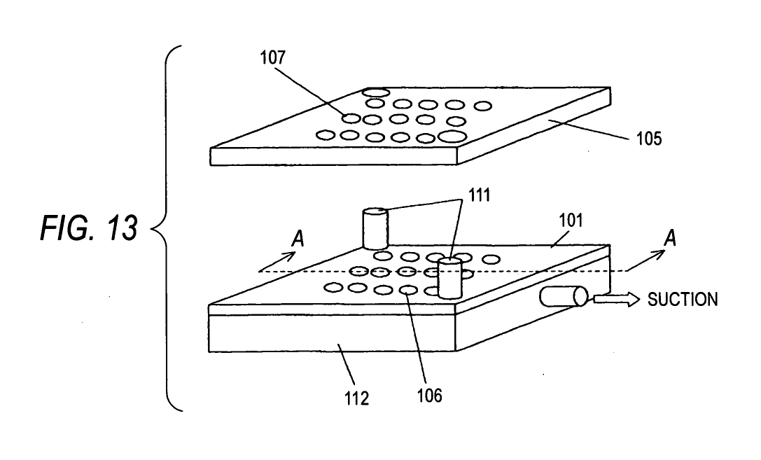

FIG. 13 is an enlarged perspective view of FIG. 8.

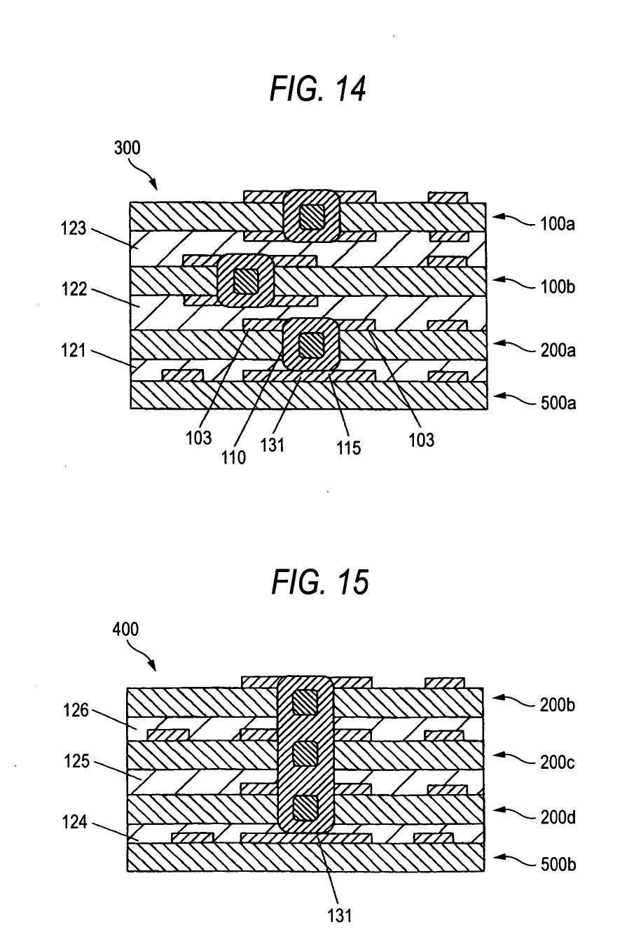

FIG. 14 is a cross-sectional view of essential parts of a multilayer FPC after lamination according to a second embodiment of the present invention.

FIG. 15 is a cross-sectional view of essential parts of another multilayer FPC after lamination according to the second embodiment of the present invention.

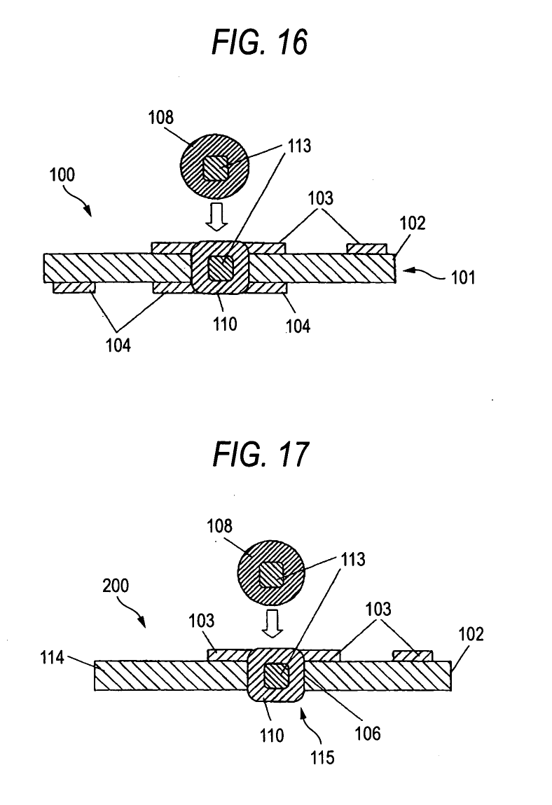

FIG. 16 is a cross-sectional view of essential parts of a multilayer FPC before lamination according to the second embodiment of the present invention.

FIG. 17 is a cross-sectional view of essential parts of a multilayer FPC before lamination according to the second embodiment of the present invention.

### DETAILED DESCRIPTION OF THE PREFERRED EMBODIMENTS

An interlayer connection conductor according to an embodiment of the invention will be described below with reference to FIGS. 1A and 1B. FIGS. 1A and 1B illustrate an interlayer connection conductor according to an embodiment of the invention. FIG. 1A is a schematic cross-sectional view and FIG. 1B illustrates main parts of multilayer FPC that is connected by an interlayer connection conductor according to an embodiment of the invention.

As shown in FIG. 1A, an interlayer connection conductor 1 is a spherical conductor that is formed by coating a soft solder metal 3 to whole surface of a metal core 2 that is a small piece of cylindrical body formed by cutting a metal fine wire.

The condition in use of an interlayer connection conductor according to an embodiment of the invention will be described below with reference to FIG. 1B. As shown in FIG. 1B, a multilayer FPC 10 is formed by bonding a one-surface FPC 4 having a wiring layer 6 through which a through hole 8 is formed and a surface of the other one-surface FPC 5 having a wiring layer 7 through an adhesive layer 9. When the interlayer connection conductor 1 is disposed into the through hole 8 of the multilayer FPC 10, the solder metal 3 of the interlayer connection conductor 1 and the metal core 2 are deformed and fill the through hole 8 with no gap. Further, the solder metal 3 is joined to both the wiring layers 6 on a surface of the one-surface FPC 4 and the wiring layer 7 on a surface of the other one-surface FPC 5. Therefore, they are electrically connected. The solder metal 3 and the wiring layers 6 and 7 are metalically jointed by a solder reflow process, and thus solidly connected.

Manufacturing method of a multilayer FPC using an interlayer connection conductor 1 according to an embodiment of the invention will be described below with reference to FIGS. 2A to 2H. FIGS. 2A to 2H illustrate manufacturing method of a multilayer FPC using the interlayer connection conductor 1 according to an embodiment of the invention.

As shown in FIG. 2A, an adhesive layer attached-one-surface copper clad laminate 13 is provided, which includes a copper foil 12 disposed on a surface of an insulating layer 11 and a sheet-shaped adhesive layer 9 formed on the other surface. In the present embodiment, although a type of two-layer having no adhesive layer between the insulating layer 11 and the copper foil 12 is provided, a type of three-layer having an adhesive layer is available. Any type of layer is available depending on circumstances and not limited to the type.

As shown in FIG. 2B, the wring layer 6 is formed by an etching process using etching solution such as a ferric chloride and copper chloride after forming a mask material on a surface of the copper foil 12. The wiring layer 6 formed as described above is not affected during processes after the etching. Accordingly, the wiring layer 6 can be miniaturized by making the copper foil 12 thin.

As shown in FIG. 2C, the through hole 8 is formed by a punching process using a punching mold 14.

As shown in FIG. 2D, after disposing the interlayer connection conductor 1 at the through hole 8, the interlayer connection conductor 1 and the adhesive layer 9 are interposed between an upper pressing plate 15 and lower pressing plate 16. The upper and lower pressing rollers press the insulating layer 11, which causes the interlayer connection conductor 1 to be forced into the through hole 8 As a result, the interlayer connection conductor 1 is deformed.

As shown in FIG. 2E, the interlayer connection conductor 1 is forced in the through hole 8 by the upper and lower pressing plates 15 and 16. When the interlayer connection conductor 1 is forced into the through hole 8, the interlayer connection conductor 1 deforms taking the shape of the inner wall of the through hole 8 while joined to a part of the wiring layer 6 because its surface is formed of the solder metal 3 that is soft metal. As a result, the interlayer connection conductor 1 is forced in the through hole 8 with no gap in the hole. Further, the interlayer connection conductor 1 comes in contact with the lower pressing plate 16 and continues deforming, finally completes the deformation in the through hole 8.

As shown in FIG. 2F, the FPC 4 having an adhesive layer on one surface is obtained, which includes an interlayer connection bump 17 formed of the interlayer connection conductor 1 protruding through an opening of the through hole 8 at the adhesive layer 9.

As shown in FIG. 2G, an interlayer connection conductor 20 is formed such that the other one-surface FPC 5 having the wiring layer 6 and the one-surface FPC 4 with an adhesive layer having the interlayer connection bump 17 are laminated through the adhesive layer 9 and the interlayer connection bump 17 is joined and electrically connected to the wiring layer 6 of the other one-surface FPC 5 by heating and pressing using an upper heating and pressing plate 18 and a lower heating and pressing plate 19.

As shown in FIG. 2H, a multilayer FPC 10 having layers connected with each other are achieved by very simple processes.

A basic material of a metal fine wire for the metal core 2 may be a soft metal, such as gold, silver, copper or copper alloy, and tin or tin alloy. As for an interlayer connection conductor 1 having soft metal core 2, the conductor may be easily forced in the hole and deform under low pressure, and thus filling the inside of the hole 8 with no gap. Therefore, the metal post-shaped interlayer conductor 20 securely jointed to the wiring layer 6 and having high conductivity is achieved. As a result, it secures joining. In particular, when a copper-based metal is used for the metal fine wire, the reliability with respect to the thermal cycle deformation becomes high and it is suitable for a product that requires high reliability because the thermal expensive rate of the insulating layer is equal to the conductor.

Surface treatment, such as gold plating, nickel plating, or solder treatment, is applied to the metal fine wire. Improved wettability is obtained in coating of the solder metal 3 on the metal core 2 of a small cylindrical piece formed by cutting the metal fine wire due to the surface treatment for the metal fine wire. As a result, the metal core 2 and the solder metal 3 may be securely integrally formed.

However, even though the solder metal 3 is not coated on the metal core 2, the interlayer connection conductor is available unless it affects the connection between the wiring layers 6.

In the present embodiment, the metal core 2 is formed of a small piece of cylindrical body formed by cutting a metal fine wire so that the metal core 2 having optimum volume may be uniformly formed with ease in the interlayer connection conductor 1 by making the metal core 2 of a small cylindrical body big or long depending on the thickness of the FPC of the diameter of the through hole 8 of the multilayer FPC 10.

Accordingly, the interlayer connection conductor 1 having uniform volume can be manufactured.

Because the metal core is formed by only cutting a metal fine wire, the metal core 2 having improved productivity at low cost is achieved comparing with conventional manufacturing method using a metal ball.

In the interlayer connection conductor 1 according to the present embodiment, uniform volume is required for the forcing and deforming. However, the interlayer connection conductor 1 may not be a complete sphere when the interlayer connection conductor 1 can be handled and positioned, and elliptical sphere is also available.

The metal core 2 is formed by cutting a small cylindrical metal fine wire with a diameter the same as or more than height. Therefore, it is possible to maintain the handling of the interlayer connection conductor 1 and the position of the small cylindrical body in positioning. Accordingly, the metal core 2 of a small piece of cylindrical body is stably disposed in the through hole 8. Because the interlayer connection conductor 1 becomes a metal post-shaped internal conductor 20 having high conductivity that fills the through hole 8 with no gap, the interlayer connection conductor 1 and the wiring layer 6 are stably joined and high connection reliability is obtained. In particular, when a copper-based metal is used for the metal fine wire, the reliability with respect to the thermal cycle deformation becomes high because the thermal expensive rate of the insulating layer 11 is equal to the conductor, and it is suitable for the interlayer connection conductor 1 of a product that requires high reliability.

The interlayer connection conductor 1 smoothly deforms with ease, because it is composed of a metal core 2 formed of a soft metal and a solder metal 3 surrounding the metal core. Therefore, the wiring layer 6 is not affected during following processes and the deformed solder metal is securely joined to the wiring layer 6. As a result high reliability in the wiring layer 6 is obtained.

As for the solder metal 3, any one of a eutectic solder, a high-temperature solder, or lead-free solder may be used under circumstances. Accordingly, when the interlayer connection conductor 1 according to the present embodiment is used, high reliability in joining is obtained with miniaturized joining of a wiring layer.

An example when the above-mentioned multilayer FPC is further layered will be described below with reference to FIGS. 3A and 3B. FIGS. 3A and 3B illustrate manufacturing method of a multilayer FPC in which the multilayer FPC of FIG. 2 is additionally layered.

As shown in FIG. 3A, after layering multilayer FPC 10 and FPC 4 having adhesive layers with a plurality of interlayer connection bumps 17, an upper heating and pressing plate 18 and a lower heating and pressing plate 19 press the FPCs with heat and the interlayer connection bumps 17 are deformed and joined to wiring layers. As shown in FIG. 3B, a multilayer FPC 21 is obtained by increasing the number of wiring layers.

The multilayer FPC 21 formed as described above has high connection reliability because the solder metals 3 around the surface of the interlayer connection bump 17 come in contact with each of the wiring layers 6 in layering and securely electrically come in contact with the surface of the wiring layer 6 through the pressed-deformation. Because the contacting portion is the solder metal 3, when it undergoes heating/cooling in layered and contact conditions, the interlayer bumps 17 and the wiring layers are simply joined with each other through melt-solidification of the solder metal 3. Therefore, the connection reliability is further improved. The above multilayer FPC 21 has high connection reliability and may be further decreased in size because the components involved are reliable in joining and miniaturized wiring layers are provided.

Manufacturing method of an interlayer connection conductor according to an embodiment of the invention will be described hereafter, with reference to FIGS. 4A to 4D, 5A to 5C and 6A to 6C.

Manufacturing method of an interlayer connection conductor according to an embodiment of the invention using a solder paste as a solder metal will be described below with reference to FIGS. 4A to 4D. FIGS. 4A to 4D illustrate manufacturing method of an interlayer connection conductor according to an embodiment of the invention using solder paste.

As shown in FIG. 4A, a metal fine wire 22 moves at a predetermined amount and is cut by a predetermined distance by a cut mold 23, finally a small cylindrical metal core 2 is obtained. The metal fine wire 22 has constant diameter and moves at a predetermined amount, and thus metal cores 2 have uniform volume. The metal core 2 is manufactured through a simple process of the movement of the metal fine wire 22 and cutting of the cut mold 23, and thus improving productivity.

As shown in FIG. 4B, a metal core 2 is disposed in recesses on a thermal resistant substrate 24. The recess may have bowl shape.

The thermal resistant substrate 24 may be a metal plate such as a stainless plate. In the present embodiment, a solder is not attached when melted and SUS304 is used considering thermal resistance, chemical resistance, and machinability, but not limited.

As shown in FIG. 4C, a solder paste 25 is applied to the metal cores 2 disposed on the thermal resistant substrate 24 to cover them according to dispenser method or screen-print method to adjust the applied amount. Because the volume of the interlayer connection conductor depends on the volume of the applied solder and the metal core 2, the amount of the solder to be applied needs to be adjusted.

As shown in FIG. 4D, the predetermined amount of solder paste 25 applied to the metal core 2 to cover them undergoes heating/cooling and forms a unit with them. Therefore, a substantially spherical interlayer connection conductors 1 having uniform volume are manufacture.

As described above, an interlayer connection conductor is manufactured through a simple process including forming the metal cores 2 by cutting a metal fine wire, disposing the metal cores 2 at predetermined positions on the thermal resistant substrate 24, applying a predetermined amount of solder paste on the metal cores 2, and integrally forming the solder paste with the metal core 2 in a spherical shape by heating and melting the solder paste. Therefore, an interlayer connection conductors having uniform volume can be manufactured with improved productivity.

Manufacturing method of an interlayer connection conductor according to an embodiment of the invention using solder balls as a solder metal will be described below with reference to FIGS. 5A to 5C. FIGS. 5A to 5C illustrate manufacturing method of an interlayer connection conductor according to an embodiment of the invention using solder balls. In description of FIGS. 5A to 5C, the same parts as in FIGS. 4A to 4D are referred to the same reference numerals and not described.

As shown in FIG. 5A, a metal core 2 is disposed in recesses formed on a thermal resistant substrate 24.

As shown in FIG. 5B, solder balls 26 having predetermined uniform volume are disposed to be contact with the metal cores 2 disposed on the thermal resistant substrate 24. Solder balls 26 having predetermined uniform volume are easily provided in advance and interlayer connection conductors having further uniform volume are achieved.

As shown in FIG. 5C, substantially spherical interlayer connection conductor 1 having uniform volume can be manufactured by heating and melting the solder balls 26 that are in contact with the metal cores 2 and integrally forming them with the metal cores 2. In order to improve the wettability of the solder metal to the metal core when heating and melting of the solder ball 26, surface treatment, such as gold plating or solder plating, is applied to the surface of the fine wire forming the metal fine wire 22. Further, flux for improving the solder wettability when heating and melting may be used.

Manufacturing method of an interlayer connection conductor according to en embodiment of the invention using a metal fine wire coated with a solder metal will be describe below with reference to FIGS. 6A to 6C. FIGS. 6A to 6C illustrate manufacturing method of an interlayer connection conductor using metal fine wire coated with a solder metal. As for description about FIGS. 6A to 6C, the same parts as in FIGS. 4A to 4D and 5A to 5C are referred to the same reference numerals and not described.

As shown in FIG. 6A, a solder-coated metal fine wire 28 formed by uniformly coating a solder metal layer 27 in advance to the surface of the metal fine wire 22 is cut into a predetermined length by the cut mold 23, as it moves at a predetermined amount. Accordingly, a solder-coated metal core 30 is manufactured by coating a solder layer 29 having uniform volume around the small cylindrical metal core 2.

In the solder-coated metal core 30, because the diameter of the metal fine wire 22 composing the solder-coated metal fine wire 28 and the thickness of the solder metal layer 27 coating the surface of the metal fine wire 22 are constant and the solder-coated metal fine wire 28 is cut into a predetermined length by adjusting the amount of its movement, uniform volume of the metal core 2 and the solder metal layer 29 is simultaneously obtained. Further, the solder-coated metal core 30 can be manufactured through a simple process of the moving of the solder-coated metal fine wire 28 and cutting of the cut mold 23, and the terms of regular amount and independence in the metal core 2 and the solder metal are simultaneously obtained. Accordingly, it improves the productivity.

As shown in FIG. 6B, a solder-coated metal core 30 is disposed in recesses formed on the thermal resistant substrate 24.

As shown in FIG. 6C, a solder-coated metal core 30 is deformed in a substantially spherical shape by heating and melting the solder metal layer 29 on the surface. Therefore, a substantially spherical interlayer connection conductor 1 is obtained.

In FIGS. 6A to 6C, the solder metals are melted by heating and melting on the thermal resistant substrate 24. However, the interlayer connection conductor 1 may be manufactured by directly putting the solder-coated metal core 30 formed in FIG. 6A in hot oil and heating and melting. The productivity may be further improved through the above process.

In the manufacturing method of the interlayer connection conductor 1 according to embodiments of the invention through the processes as described above, the interlayer connection conductor 1 having improved productivity can be manufactured through simple processes of cutting of a metal fine wire and heating and melting of a solder metal because it has a substantially spherical shape having uniform volume. Therefore, the interlayer connection conductor 1 can be used as an interlayer connection conductor of multilayer FPC having small wiring layers with high connection reliability.

Hereinafter, a method of manufacturing a multilayer flexible printed circuit board according to another embodiment of the present invention will be described. First, the multilayer flexible printed circuit board according to the embodiment of the present invention will be described with reference to FIG. 7. FIG. 7 is a cross-sectional view of essential parts of a multilayer flexible printed circuit board 100 that is formed by the application of the present invention.

In the multilayer EPC 100 shown in FIG. 7, an interlayer connector 110 is formed by melting a substantially spherical conductor that is press-fitted in a through hole 106 with a hot plate at the top and bottom thereof, thereby electrically connecting an upper wiring layer 103 and a lower wiring layer 104.

Next, the method of manufacturing the multilayer FPC 100 according to the present embodiment will be described in detail with reference to FIGS. 8 to 12. According to the embodiment, the electrical connection between the upper wiring layer 103 and the lower wiring layer 104 can be realized with high reliability.

FIGS. 8 to 12 are views illustrating the manufacturing process of the multilayer FPC 100 according to the present embodiment. FIG. 8 is a cross-sectional view of the essential parts illustrating a state in which a classification mask 105 is laid over the top surface of a double-sided flexible printed circuit board 101 in which the through hole 106 is formed. FIG. 9 is a cross-sectional view of the essential parts illustrating a state in which the substantially spherical conductor 108 is introduced into the through hole 106 of the double-sided flexible printed circuit board 101 by the classification mask 105. FIG. 10 is a cross-sectional view of the essential parts illustrating a state in which the substantially spherical conductor 108 that is classified by the classification mask 105 is suctioned into the through hole 106 of the double-sided flexible printed circuit board 101. FIG. 1 is a cross-sectional view of the essential parts illustrating a state in which the substantially spherical conductor 108 is suctioned and press-fitted into the through hole 106 of the double-sided flexible printed circuit board 101. FIG. 12 is a cross-sectional view of the essential parts illustrating a state in which the substantially spherical conductor 108 that is press-fitted in the through hole 106 of the double-sided flexible printed circuit board 101 is melted to electrically connect each layer. FIG. 13 is an enlarged perspective view of FIG. 8.

As shown in FIG. 13, a positioning pin 111 for positioning the classification mask 105, the double-sided flexible printed circuit board 101, and a fixing plate 112 is formed at a predetermined position of the double-sided flexible printed circuit board 101. As the positioning pin 111 is used in aligning a classification mask opening 107 of the classification mask 105 with the through hole 106 of the double-sided flexible printed circuit board 101, the classification mask opening 107 of the classification mask 105 and the through hole 106 of the double-sided flexible printed circuit board 1 can be accurately and reliably positioned.

In FIGS. 8 to 12, the double-sided flexible printed circuit board 101 includes an insulating layer 102 made of a polyimide film on whose both sides the upper wiring layer 103 and the lower wiring layer 104 are formed, and the through hole 106 is formed through the insulating layer 102, the upper wiring layer 103, and the lower wiring layer 104. The classification mask 105 has the classification mask opening 107 for classifying and positioning the substantially spherical conductor 108 with respect to the through hole 106 in the double-sided flexible printed circuit board 101. A hot plate 109 is a means for heating and pressing the substantially spherical conductor 108 that is inserted in the through hole 106.

To manufacture the multilayer FPC 100 according to the present embodiment, as shown in FIG. 8, the through hole 106 of the double-sided flexible printed circuit board 101 is aligned with the classification mask opening 107 of the classification mask 105, and the classification mask 105 is laid over the top surface of the double-sided flexible printed circuit board 101. The through hole 106 of the double-sided flexible printed circuit board 101 can be easily aligned with the classification mask opening 107 of the classification mask 105, as a positioning hole is formed at each predetermined position and the positioning pin of a base plate is inserted in each positioning hole.

Next, as shown in FIG. 9, the substantially spherical conductor 108 is mounted on the classification mask 105, and then is suctioned into the through hole 106 of the double-sided flexible printed circuit board 101 while pressure is controlled by using a vacuum pump, and ultrasonic vibration is applied on the classification mask 105. By performing suction and ultrasonic vibration, the substantially spherical conductor 108 can be easily induced in the classification mask opening 107 of the classification mask 105, and the substantially spherical conductor 108 can be easily and reliably introduced in the classification mask opening 107 of the classification mask 105.

Next, after the substantially spherical conductor 108 is classified to be accommodated in the classification mask opening 107 of the classification mask 105, as shown in FIG. 10, the substantially spherical conductor 108 is arranged in the through hole 106. Here, the arrangement of conductor in the through hole can be verified by vacuum of suction. Accordingly, the arrangement of conductor can be verified instantly and easily, which leads to a higher productivity.

Next, as shown in FIG. 11, after the substantially spherical conductor 108 is press-fitted in the through hole 106, the press-fitted substantially spherical conductor 108 is melted by the hot plate 109 at the top and bottom and molded to thoroughly fill the inside of the through hole 106, which forms the interlayer connector 110 electrically connecting the upper wiring layer 103 and the lower wiring layer 4. Next, when the hot plate 109 is removed, as shown in FIG. 7, the multilayer FPC 100 is completed in which the upper wiring layer 103 and the lower wiring layer 104 are electrically connected to each other by the interlayer connector 110.

In the manufacturing method, an insulated plastic film with high flexibility is used as the insulating layer 102 that is used in the double-sided flexible printed circuit board 101 with wiring layers on both sides thereof The insulating plastic film includes polyimide film, polyethylene film, polyethylene terephthalate film, polyethylene naphthalate film, polyether nitryl film, etc.

The double-sided flexible printed circuit board 101 is not limited to having the insulating layer 102 with wiring layers on both sides thereof That is, the double-sided flexible printed circuit board 101 may use an insulating film with wiring layers on both sides thereof, or may use a pair of insulating films attached to each other, and each insulating film has a wiring layer on one side thereof.

The metal used in forming wiring layers may be various kinds of conductive metal such as copper, gold, and nickel. The substantially spherical conductor 108 may be a solder ball, a copper ball, a copper core solder ball, a copper core metal ball, a resin core solder ball, a resin core metal ball, etc.

In general, since the conductor for connecting layers of the multilayer FPC should be smoothly introduced in the through hole for interlayer connection, the conductor is preferably a spherical conductor having high sphericity and little variations in particle diameter. However, a method of manufacturing the spherical conductor satisfying the above-mentioned requirements is not suitable for mass production, which causes cost of the spherical conductor to rise.

However, according to the present invention, the conductor can be classified and arranged at the same time by the classification mask 105, which may reduce the requirements for the substantially spherical conductor 108 used as the conductor. Therefore, it is possible to use a substantially spherical conductor that is obtained by, for example, an atomizing method suitable for mass production, which may contribute to cost reduction.

As a method of forming a desirably sized through hole 106 in a predetermined position of the double-sided flexible printed circuit board 101, conventional methods such as drilling, punching, and laser processing can be used. The shape of the through hole 106 is not particularly limited, but the substantially spherical conductor 108 is preferably formed in a circular shape so as to be evenly press-fitted in the two wiring layers. The diameter of the through hole 106 may differ according to the thickness of the multilayer FPC, preferably, in the range of 100 μm to 500 μm.

The classification mask 105 may be formed as an opening with the size of 0.2 mm to 1.0 mm is formed at a metal thin plate with the size of 0.1 mm to 0.3 mm, such as 42 alloy, stainless, and coppers, by laser. In the present invention, the diameter of the classification mask opening 107 of the classification mask 105 is preferably larger than that of the though hole 106 of the double-sided flexible printed circuit board 101 Otherwise, when the diameter of the classification mask opening 107 is equal to or smaller than that of the through hole 106 of the double-sided flexible printed circuit board 101, the substantially spherical conductor 108 dropped through the classification mask opening 107 in the through hole 106 of the double-sided flexible printed circuit board 101 cannot thoroughly fill the through hole 106 of the double-sided flexible printed circuit board 101, which may deteriorate interlayer connection.

According to the present embodiment, the method of manufacturing the multilayer FPC 100 has characteristics as follows. As the substantially spherical conductor 108 is classified using the classification mask 105, interlayer connection inside the through hole 106 is optimized, thereby obtaining high reliability. Further, ultrasonic vibration is applied to have the substantially spherical conductor 108 accommodated in the classification mask opening 107 of the classification mask 105, which makes unnecessary maintenance such as a jig for accommodation. Therefore, the substantially spherical conductor 108 can be efficiently accommodated in the classification mask opening 107 of the classification mask 105, thereby achieving higher productivity. In addition, as the classification mask opening 107 of the classification mask 105 is aligned with the through hole 106 of the double-sided flexible printed circuit board 101 using the positioning pin 111, suction is performed by controlling vacuum pressure into the through hole 106, which eliminate the possibility that the substantially spherical conductor 108 is wrongly arranged in the through hole 106. Therefore, the substantially spherical conductor 108 can be easily and reliably arranged in the through hole 106, which leads to higher reliability and productivity.

According to the present embodiment, the flexible printed circuit board does not have a connection layer among the insulating layer 102, the upper wiring layer 103 and the lower wiring layer 104. However, the kind of flexible printed circuit board is not limited thereto in the present invention. For example, a flexible printed circuit board having a connection layer or a pair of flexible printed circuit boards attached to each other—each flexible printed circuit board has a wiring layer on one side thereof—can be used, otherwise, a desired type of flexible printed circuit board can be used.

According to further embodiment, the above-described multilayer FPC is further laminated. FIG. 14 is a cross-sectional view of essential parts of a multilayer FPC 300 according to the second embodiment. FIG. 15 is a cross-sectional view of essential parts of a multilayer FPC 400 according to the second embodiment.

In FIG. 14, the multilayer FPC 3 00 is formed by laminating two multilayer FPC 100a, 100b manufactured by the manufacturing method of the present invention described in the first embodiment, a multilayer FPC 200a manufactured by the manufacturing method of the present invention described in the first embodiment and a one-sided printed circuit board 500a with connection layers 121, 122 and 123 interposed therebetween.

In the multilayer FPC 300, component members composed of the multilayer FPC 100a, 100b, and 200a have high interlayer connection reliability and fine wiring layers. Also, component members composed of the multilayer FPC 200a and the one-sided printed circuit board 500a have high interlayer connection reliability. Therefore, even though the multilayer FPC 300 is formed of more wiring, layers, as compared to that of the first embodiment, the multilayer FPC is realized with high interlayer connection reliability and fine wiring layers.

To manufacture the multilayer FPC 300, as shown in FIG. 16, the multilayer FPC 100(a and b) is manufactured by the method of manufacturing the multilayer FPC according to the present invention. That is, as the substantially spherical conductor 108 is press-fitted and deformed in the through hole 106 of the double-sided flexible printed circuit board 101, in which the upper wiring layer 103 and the lower wiring layer 104 are formed on both sides of the insulating layer 102 made of a polyimide film, so as to fill the interlayer connector 110, the multilayer FPC 100(a and b) in which the upper wiring layer 103 and the lower wiring layer 104 are electrically connected is manufactured.

The interlayer connector 110 of FIG. 16 is formed by melting and solidifying a substantially spherical copper core solder ball having a copper-based core 113 therein. The composition of the copper core solder ball is not limited, eutectic solder, high temperature solder, and Sn—Ag—Cu alloy or the like can be used.

Next, as shown in FIG. 17, the multilayer FPC 200a is manufactured by the method of manufacturing the multilayer FPC 100 according to the present invention. That is, as the substantially spherical conductor 108 is press-fitted and deformed in the through hole 106 of the one-sided flexible printed circuit board 114, in which the upper wiring layer 103 is formed on one side of the insulating layer 102 made of a polyimide film, so as to fill the interlayer connector 110, and thus the multilayer FPC 200a is manufactured in which an interlayer connection bump 115 is formed in contact with the upper wiring layer 103 to protrude from the one-sided flexible printed circuit board 114.

Next, the multilayer FPC 200a is laminated on the one-sided printed circuit board 500a for bonding through the connection layer 121. Accordingly, the multilayer FPC 200a can be electrically connected to the wiring layer 131 of the one-sided printed circuit board 500a by the interlayer connection bump 115, which makes easy to form a multilayer. The multilayer FPC 100 in which the multilayer FPC 200a is laminated on the one-sided printed circuit board 500a is laminated on the multilayer FPC 100b for bonding through the connection layer 122. Further, the multilayer FPC 100 in which the printed circuit board 500a, the multi layer FPC 200a, and the multilayer FPC 100b are laminated on each other is laminated on the multilayer FPC 100a for bonding through the connection layer 123. By this, the multilayer FPC 300 having more wiring layers can be easily manufactured. The order of laminations is not particularly limited, and can be modified.

In FIG. 15, the multilayer FPC 400 is formed by laminating three multilayer FPC 100c, 110d and 100e, manufactured by using the method of manufacturing the multilayer FPC according to the present invention, and a one-sided printed circuit board 500b through the connection layers 124, 125 and 126.

In the multilayer FPC 400 component members composed of the multilayer FPC 100c, 100d, and 100e and the one-sided printed circuit board 500b have high interlayer connection reliability and fine wiring layers. Therefore, even though the multilayer FPC 400 is formed of more wiring layers, as compared to that of the first embodiment, the multilayer FPC is realized with high interlayer connection reliability and fine wiring layers.

To manufacture the multilayer FPC 400, as shown in FIG. 17, the multilayer FPC 200(a and b) is manufactured by the method of manufacturing the multilayer FPC according to the present invention. That is, as the substantially spherical conductor 108 is press-fitted and deformed in the through hole 106 of the one-sided flexible printed circuit board 114, in which the upper wiring layer 103 is formed on one side of the insulating layer 102 made of a polyimide film, so as to fill the interlayer connector 110, and thus the multilayer FPC 200(b, c and d) is manufactured in which the interlayer connection bump 115 is formed in contact with the upper wiring layer 103 to protrude from the one-sided flexible printed circuit board 114.

Next, the multilayer FPC 200d is laminated on the one-sided printed circuit board 500b for bonding through the connection layer 124, so that the wiring layer 131 of the one-sided printed circuit board 500b is in contact with the interlayer connector 110 of the multilayer FPC 200d. Accordingly the multilayer FPC 200d can be electrically connected to the wiring layer 131 of the one-sided printed circuit board 500b by the interlayer connector 110, which makes easy to form a multilayer. The multilayer FPC in which the multilayer FPC 200d is laminated on the one-sided printed circuit board 500b is laminated on the multilayer FPC 200c for bonding through the connection layer 125.

Further, the multilayer FPC in which the printed circuit board 500b, the multi layer FPC 200d, and the multilayer FPC 200c are laminated on each other is laminated on the multilayer FPC 200b for bonding through the connection layer 126. By this, as wiring layers of the component members are electrically connected to each other, the multilayer FPC 400 having more wiring layers can be easily manufactured. The order of laminations is not particularly limited, and can be modified.

An interlayer connection conductor according to the invention is preferable to connection between wiring layers of multilayer FPC on which a variety of surface-mounting type components are mounted because of high connection reliability, optimally miniaturized wiring layers, and improve productivity.

This application is based upon and claims the benefit of priorities of Japanese Patent Application No. 2005-165125 filed on Jun. 6, 2005 and No. 2005-277758 filed on Sep. 26, 2006, the contents of which are incorporated herein by reference in its entirety.

1. An interlayer connection conductor, which is formed in a substantially spherical shape and is press-fitted in a through hole formed in a printed circuit board in a thickness direction so as to serve an interlayer connector, the printed circuit board having a wiring layer that is formed on at least one side of an insulating layer, the interlayer connection conductor comprising:
a metal core that is a small piece formed by cutting a metal wire; and
a solder metal that covers the surface of the metal core.

2. The interlayer connection conductor according to claim 1, wherein the metal core is a cylindrical small piece formed by cutting the metal wire.

3. The interlayer connection conductor according to claim 2, wherein the metal core is formed such that a diameter of the cylindrical small piece is equal to or larger than a height of the metal core.

4. The interlayer connection conductor according to claim 1, wherein the metal core is formed by cutting the metal wire formed of one or more kinds of soft metal.

5. The interlayer connection conductor according to claim 1, wherein the metal core is formed by cutting the metal wire including at least copper or copper alloy.

6. The interlayer connection conductor according to claim 1, wherein the solder metal is a solder alloy.

7. The interlayer connection conductor according to claim 1, wherein the printed circuit board is a flexible printed circuit board.

8. A method of manufacturing an interlayer connection conductor comprising:
cutting a metal wire by a predetermined length to form a metal core;
disposing the metal core in a recess of a heat resistant substrate;
coating a solder metal to cover the metal core disposed in the recess; and
covering the metal core with the solder metal in a substantially spherical shape by heating and melting the solder metal.

9. The method of manufacturing an interlayer connection conductor according to claim 8, wherein the solder metal is a cream soldering paste.

10. The method of manufacturing an interlayer connection conductor according to claim 8, wherein the solder metal is a solder ball.

11. The method of manufacturing an interlayer connection conductor according to claim 8, wherein the solder-covered metal core having a solder metal covered on its outer peripheral surface is formed by cutting a solder-covered metal wire in a predetermined length, the surface of the solder-covered metal wire being covered with a solder metal layer at a predetermined thickness.

12. A flexible printed circuit board comprising:
a wiring layer that is formed on at least one side of an insulating layer, a metal core that is a small piece formed by cutting a metal wire; and
an interlayer connection conductor that is formed of a solder metal covering the surface of the metal core,
wherein the interlayer connection conductor is press-fitted in a through hole formed in the flexible printed circuit board in a thickness direction.
